(19) United States
(12) Patent Application Publication
(10) Pub. No.: US 2026/0144020 A1
(43) Pub. Date: May 21, 2026

(54) WAFER PROCESSING METHOD

(71) Applicant: DISCO CORPORATION, Tokyo (JP)

(72) Inventors: Akira MIZUTANI, Tokyo (JP); Hayato TANAKA, Tokyo (JP)

(21) Appl. No.: 19/377,378

(22) Filed: Nov. 3, 2025

(30) Foreign Application Priority Data
Nov. 18, 2024 (JP) 2024-200595

(51) Int. Cl. H01L 21/02; B23K 26/53; B23K 101/40; H01L 21/304; H01L 21/67

(52) U.S. Cl. CPC H10P 90/128; B23K 26/53; H10P 52/00; H10P 72/0428; H10P 90/124; B23K 2101/40

(57) ABSTRACT

A wafer processing method for processing a bonded wafer in which a first wafer and a second wafer are bonded includes forming a ring-shaped modified layer at an outer periphery of the first wafer by applying a laser beam having a wavelength with transmittability, with a focal point of the laser beam positioned at an inner side adjacent to the chamfered portion; forming a release layer in a region in which the chamfered portion is to be removed by causing a fluid that weakens a bonding force between the first wafer and the second wafer to penetrate into a bonding surface between the first wafer and the second wafer; and before the forming the release layer, forming unevenness for facilitating entry of the fluid by applying a laser beam with a focal point of the laser beam positioned in the region in which the chamfered portion is to be removed.

### BACKGROUND

### 1. Technical Field

The present disclosure relates to a wafer processing method for processing a bonded wafer in which a first wafer and a second wafer are bonded.

### 2. Description of the Related Art

A wafer having multiple devices such as ICs and LSIs, which are formed on a surface and defined by division lines, is ground at its back surface to be thinned by a grinding apparatus, and is then divided into individual device chips using a dicing apparatus and a laser processing apparatus to be used in electrical devices such as mobile phones, personal computers, and electrical equipment.

Also, a wafer has a chamfered portion at its outer periphery. This chamfered portion forms a sharp knife edge when the back surface of the wafer is ground. This may cause a problem in that a crack is formed from the knife edge to the inner side, damaging devices formed in the central region, and a problem in that the chamfered portion that forms a knife edge hurts an operator, for example. As such, a technique for removing the chamfered portion from the wafer has been proposed (see, for example, JP 2020-088187 A).

### SUMMARY

However, the technique in which a first wafer and a second wafer are bonded to form a bonded wafer and improve device functionality, and then the back surface of the first wafer is ground has a problem in that removing the chamfered portion from the first wafer is relatively difficult.

In particular, a wafer bonded by siloxane bonding (Si—O—Si bonding) has a strong bonding force. Even if a laser beam having a wavelength that is transmittable through the first wafer is applied at a focal point located on the inner side adjacent to the chamfered portion to form a modified layer inside the first wafer, it is difficult to satisfactorily remove the chamfered portion by that alone. Furthermore, although a chamfered portion can be removed using a cutting blade, this may damage the other wafer (second wafer) that is bonded.

In view of the foregoing facts, a main technical issue of the present disclosure is to provide a wafer processing method capable of appropriately removing a chamfered portion of a first wafer when a bonded wafer in which the first wafer and a second wafer are bonded is processed.

In order to solve the above-mentioned main technical issue, according to the present disclosure, there is provided a wafer processing method for processing a bonded wafer in which a first wafer and a second wafer are bonded, the wafer processing method including: forming a ring-shaped modified layer at an outer periphery of the first wafer by applying a laser beam having a wavelength with transmittability, with a focal point of the laser beam positioned at an inner side adjacent to the chamfered portion; and before, after, or at a same time as the forming the modified layer, forming a release layer in a region in which the chamfered portion is to be removed by causing a fluid that weakens a bonding force between the first wafer and the second wafer to penetrate into a bonding surface between the first wafer and the second wafer, in which the wafer processing method further includes, before the forming the release layer, forming unevenness for facilitating entry of the fluid by applying a laser beam with a focal point of the laser beam positioned in the region in which the chamfered portion is to be removed.

In the forming of unevenness, the unevenness is preferably formed along the entire circumference or a part of the region in which the chamfered portion is to be removed. Also, after the forming the modified layer and the forming the release layer, removing the chamfered portion from the first wafer may be included. Furthermore, after the forming the modified layer and the forming the release layer, grinding of an upper surface of the first wafer may be performed to thin the first wafer, and the grinding may also serve as removing the chamfered portion. Additionally, the first wafer and the second wafer are preferably bonded via Si—O—Si bonding, the fluid that weakens the bonding force preferably contains at least one of water, water vapor, mist, or ammonia, and in the forming the release layer, Si—O—Si bonding preferably changes to Si—OH—OH—Si bonding to weaken the bonding force.

A wafer processing method according to the present disclosure is a wafer processing method for processing a bonded wafer in which a first wafer and a second wafer are bonded. The wafer processing method includes: forming a ring-shaped modified layer at an outer periphery of the first wafer by applying a laser beam having a wavelength with transmittability, with a focal point of the laser beam positioned at an inner side adjacent to the chamfered portion; and before, after, or at a same time as the forming the modified layer, forming a release layer in a region in which the chamfered portion is to be removed by causing a fluid that weakens a bonding force between the first wafer and the second wafer to penetrate into a bonding surface between the first wafer and the second wafer. The wafer processing method further includes, before the forming the release layer, forming unevenness for facilitating entry of the fluid by applying a laser beam with a focal point of the laser beam positioned in the region in which the chamfered portion is to be removed. As such, the chamfered portion can be easily removed from the first wafer with the modified layer as a starting point, thereby solving a conventional problem in that the chamfered portion is relatively difficult to remove from the first wafer. Furthermore, since a cutting blade is not needed to remove the chamfered portion from the first wafer, there is no risk of damaging the second wafer forming the bonded wafer.

### BRIEF DESCRIPTION OF THE DRAWINGS

FIG. 1 is a perspective view showing a mode in which a bonded wafer is produced;

FIG. 2 is a perspective view showing a mode in which a bonded wafer is placed on a chuck table of a laser processing apparatus;

FIG. 3A is a perspective view showing a mode of forming a modified layer;

FIG. 3B is a partially enlarged cross-sectional view showing a modified layer formed in the forming of a modified layer shown in FIG. 3A;

FIG. 4 is a plan view of a first wafer in which radial modified layers are formed;

FIG. 5A is a perspective view showing an implementation mode of forming unevenness;

FIG. 5B is a partially enlarged cross-sectional view showing unevenness formed in the forming of unevenness shown in FIG. 5A;

FIG. 6A is a perspective view showing another implementation mode of forming unevenness;

FIG. 6B is a partially enlarged cross-sectional view showing unevenness formed in the forming of unevenness shown in FIG. 6A;

FIG. 7A is a perspective view showing an implementation mode of forming a release layer;

FIG. 7B is a partially enlarged side view of a mode of forming a release layer by a fluid injected in the forming of a release layer shown in FIG. 7A; and

FIG. 8 is a perspective view showing an implementation mode of grinding that also serves as removing a chamfered portion.

### DESCRIPTION OF THE PREFERRED EMBODIMENTS

Hereinafter, an embodiment of a wafer processing method according to the present disclosure will be described in detail with reference to the accompanying drawings.

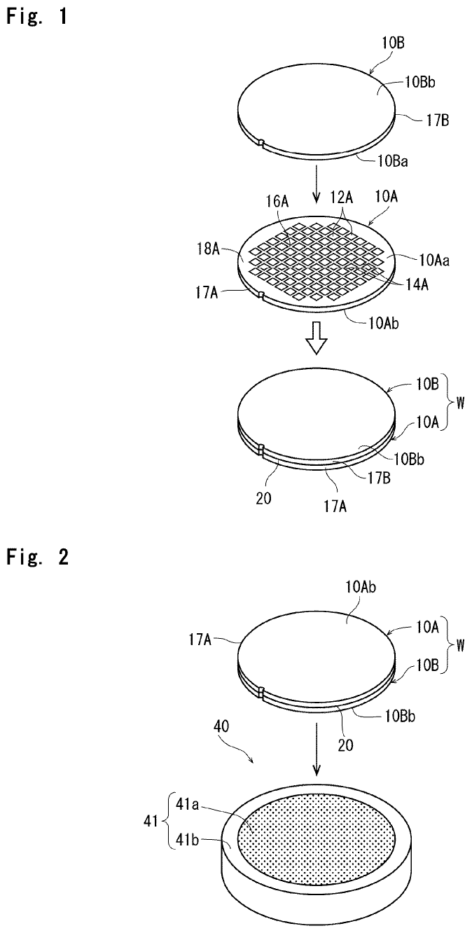

The wafer processing method according to the present disclosure processes a bonded wafer W formed by bonding a first wafer 10A and a second wafer 10B as shown in FIG. 1.

The first wafer 10A shown in FIG. 1 may be a silicon (Si) wafer having a diameter of 200 mm and a thickness of 700 μm, for example, and includes multiple devices 12A, which are formed on a surface 10Aa and defined by division lines 14A. The first wafer 10A has the surface 10Aa and a back surface 10Ab, and includes a central effective region 16A, in which the devices 12A to be used as products are formed, and an outer peripheral surplus region 18A, which includes a chamfered portion 17A with a width of 2 to 3 mm at its outer periphery and surrounds the effective region 16A. The second wafer 10B, which forms the bonded wafer W together with the first wafer 10A, has a similar configuration to the first wafer 10A, and is a silicon (Si) wafer that includes a chamfered portion 17B at its outer periphery and multiple devices (not shown) formed and defined by division lines on a surface 10Ba facing downward as viewed in the drawing. These devices correspond to the devices 12A formed on the first wafer 10A.

As shown in FIG. 1, the bonded wafer W is formed integrally by bonding the surface 10Aa of the first wafer 10A and the surface 10Ba of the second wafer 10B together to form a bonding surface 20 by siloxane bonding. The siloxane bonding is Si—O—Si bonding in which silicon (Si) and oxygen (O) are alternately bonded, and a strong bonding state can be maintained even at high temperatures because the first wafer 10A and the second wafer 10B are bonded by heat treatment.

Once the bonded wafer W of the workpiece is produced as described above, a wafer processing method of this embodiment described below is performed.

### Forming Modified Layer

To perform a wafer processing method of the present embodiment, first, a laser beam LB having a wavelength that is transmittable through the first wafer 10A is applied with its focal point positioned on the inner side adjacent to the chamfered portion 17A formed at the outer periphery of the first wafer 10A, thereby forming a ring-shaped modified layer 100 for removing the chamfered portion 17A of the first wafer 10A. The procedure is described in more detail below.

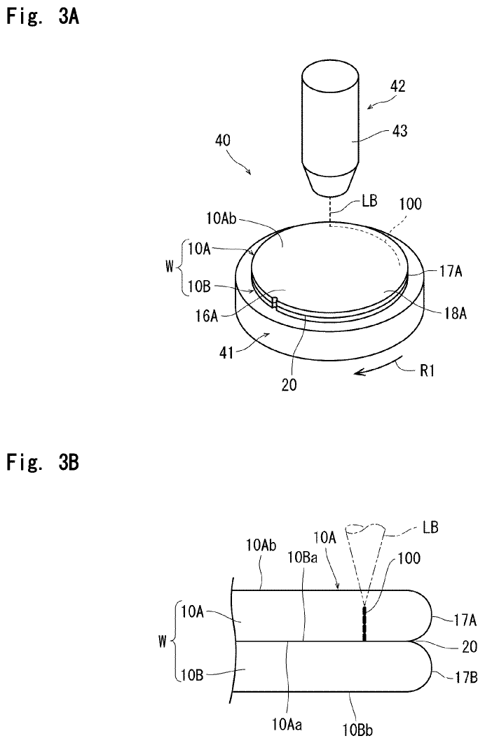

Once the bonded wafer W described above is prepared, this bonded wafer W is transported to a laser processing apparatus 40 (only a part of which is shown) shown in FIGS. 2 and 3A. The laser processing apparatus 40 includes at least a chuck table 41, which holds the bonded wafer W, and a laser beam applying unit 42, which applies a laser beam LB having a wavelength that is transmittable through the first wafer 10A. As shown in FIG. 2, the chuck table 41 includes a holding surface 41a, which is made of a breathable material, and a frame 41b surrounding the holding surface 41a, and is connected to a suction unit (not shown) via the frame 41b. By operating the suction unit, a negative pressure is generated at the holding surface 41a.

The bonded wafer W transported to the laser processing apparatus 40 is placed on the chuck table 41 with the first wafer 10A, from which the chamfered portion 17A is to be removed, facing upward as shown in FIG. 2. The above-mentioned suction unit is activated to generate negative pressure at the holding surface 41a, so that the bonded wafer W is held by suction on the chuck table 41. Then, using an alignment unit (not shown) disposed in the laser processing apparatus 40, alignment is performed on the bonded wafer W held by suction on the chuck table 41. This alignment detects the position of the outer periphery edge where the chamfered portion 17A of the first wafer 10A is formed, the center position of the first wafer 10A, and the height of the upper surface, which is the back surface 10Ab, of the first wafer 10A so as to detect a processing position to which the focal point of the laser beam LB is positioned to apply the laser beam LB on the inner side adjacent to the chamfered portion 17A formed at the outer periphery of the first wafer 10A.

Based on the information on the processing position detected by the above-mentioned alignment, the chuck table 41 is moved to position the processing position, which is set on the first wafer 10A of the bonded wafer W, directly below a focusing unit 43 of the laser beam applying unit 42, as shown in FIG. 3A. Then, as can be understood from FIG. 3B in addition to FIG. 3A, the laser beam LB is applied from the side corresponding to the back surface 10Ab of the first wafer 10A with the focal point of the laser beam LB positioned inside the processing position of the first wafer 10A, and the chuck table 41 is rotated in the direction indicated by arrow R1 in FIG. 3A to form a ring-shaped modified layer 100 along the inner side of the chamfered portion 17A of the first wafer 10A.

The modified layer 100 described above is preferably formed by multiple layers in the up-down direction as shown in FIG. 3B. For example, the modified layer 100 shown in FIG. 3B is formed by four modified layers arranged in the up-down direction. To form the modified layer 100 including such multiple layers, first, the focal point of the laser beam LB is positioned on the inner side adjacent to the chamfered portion 17A of the first wafer 10A, more specifically, at position 2.5 mm inward from the outer peripheral edge of the first wafer 10A such that a modified layer is formed, for example, at a depth of 700 μm from the back surface 10Ab of the first wafer 10A, that is, near the surface 10Aa inside the first wafer 10A. The laser beam LB is applied while rotating the chuck table 41 in the direction indicated by arrow R1 described above, to form a ring-shaped modified layer of the first layer. Then, while rotating the chuck table 41, the focal point is raised three times toward the back surface 10Ab (upward) such that the depth of the formed modified layer 100 from the back surface 10Ab is shifted to 500 μm, to 300 μm, and then to 150 μm, for example, thereby forming a total of four ring-shaped modified layers 100 along the chamfered portion 17A. The modified layer 100 shown in FIG. 3B is conceptually illustrated for the sake of illustration, and the sizes and depth positions of the layers are not in accordance with the actual dimensions. The forming of the modified layer is completed as described above. The modified layer 100 described above is not limited to being formed of four layers, and an appropriate number of layers may be set depending on the wavelength and output of the laser beam LB applied by the laser beam applying unit 42, the thickness of the first wafer 10A, the material of the first wafer 10A, and the like.

The laser processing conditions used in forming the modified layer described above may be set to the following laser processing conditions, for example.
Wavelength: 1342 nm
Repetition frequency: 80 kHz
Processing feed rate: 60 rpm (rotation speed of the chuck table 41)
Average output: 2.0 W

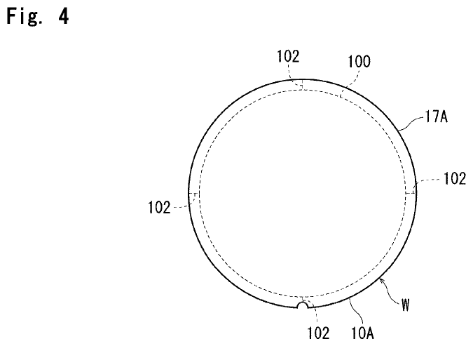

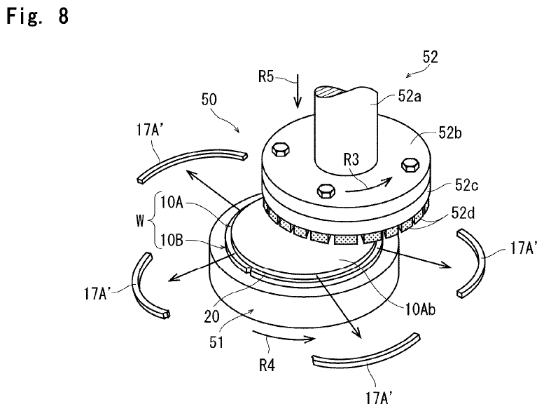

As shown in FIG. 4, forming the modified layer as described above may form radial modified layers 102 that extend from a region in which the modified layer 100 is formed to the outer side where the chamfered portion 17A is formed, for example. The illustrated radial modified layers 102 may be formed, for example, by applying a laser beam LB with a wavelength, repetition frequency, and average output similar to those used to form the modified layer 100 described above, and are formed at multiple locations (four locations in the illustrated embodiment) at equal intervals around the outer periphery of the first wafer 10A. By forming these radial modified layers 102, the chamfered portion 17A is separated into multiple broken pieces 17A′ (see FIG. 8) when the chamfered portion 17A is removed from the first wafer 10A by the removing of the chamfered portion, which will be described below, allowing the chamfered portion 17A to be removed in a desirable manner.

### Forming Unevenness

Then, before forming a release layer, which will be described below, forming of unevenness is performed in which a laser beam LB is applied with its focal point positioned in a region of the first wafer 10A in which the chamfered portion 17A is to be removed, to form unevenness 120, which facilitates entry of a fluid L supplied in forming a release layer for weakening the bonding force at the bonding surface 20 described above. The specific procedure for forming unevenness is described below.

In forming unevenness, first, alignment is performed in which the bonded wafer W held on the chuck table 41 of the laser processing apparatus 40 described above is imaged with an alignment unit (not shown) to detect a region in which unevenness is to be formed by applying a laser beam LB, more specifically, a processing region in which unevenness is to be formed described below and that corresponds to the region of the first wafer 10A forming the bonded wafer W in which the chamfered portion 17A is to be removed. When the forming of unevenness is performed immediately after the forming of a modified layer described above, the above alignment can be performed simultaneously with the alignment performed in forming the modified layer. In this case, it is not necessary to perform alignment again after forming the modified layer as described above. After forming the modified layer described above, an X-axis feed unit (not shown) for moving the chuck table 41 in the X-axis direction and a Y-axis feed unit (not shown) for moving the chuck table 41 in the Y-axis direction perpendicular to the X-axis direction are operated to position a predetermined processing region of the bonded wafer W in which unevenness is to be formed directly below the focusing unit 43.

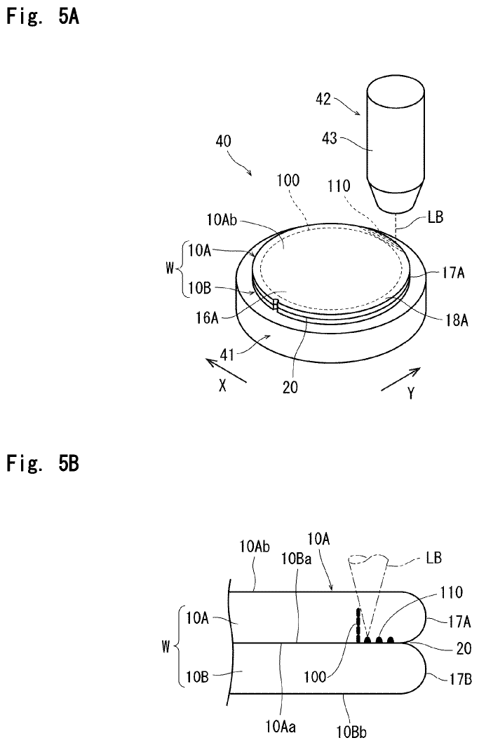

Then, as shown in FIG. 5A, the X-axis feed unit and the Y-axis feed unit are operated to move the chuck table 41 such that the focal point of the laser beam LB is positioned near the surface 10Aa of the first wafer 10A facing the bonding surface 20 in the region corresponding to the region of the chamfered portion 17A to be removed. The laser beam LB is applied while feeding the first wafer 10A in the X-axis direction for processing to form unevenness 110 formed by linear modified layers. The unevenness 110 is preferably formed by multiple modified layers as shown in FIG. 5B, and formed by applying the laser beam LB described above while indexing and feeding the chuck table 41 holding the first wafer 10A in the Y-axis direction as needed.

The above-described unevenness 110 is not limited to being formed in one location corresponding to a part of the outer peripheral region corresponding to the region in which the chamfered portion 17A is to be removed as shown in FIG. 5A, and may be formed in multiple locations in a region corresponding to the region in which the chamfered portion 17A is to be removed. Furthermore, the unevenness 110 may also be formed around the entire circumference along the region corresponding to the region in which the chamfered portion 17A is to be removed.

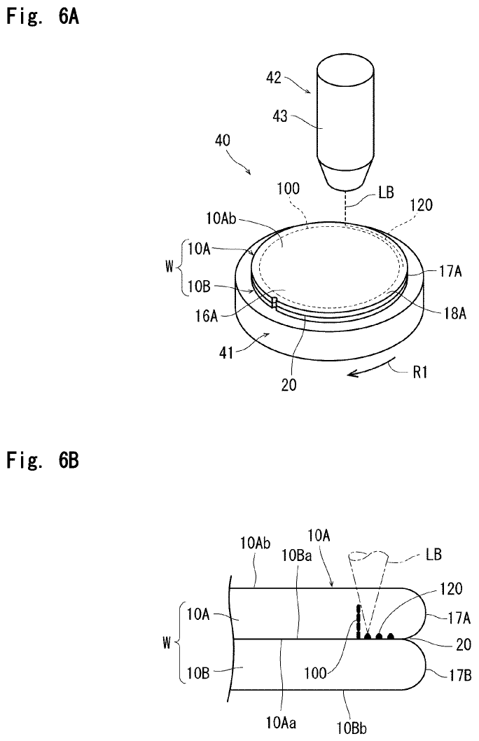

The unevenness 110 shown in FIG. 5A above is formed by multiple linear modified layers. However, the forming of unevenness of the present disclosure is not limited to this, and the unevenness may be formed by forming a ring-shaped modified layer along the inner side adjacent to the chamfered portion 17A, for example. More specifically, as shown in FIG. 6A, the focusing unit 43 of the laser beam applying unit 42 is positioned above a predetermined processing region corresponding to the region of the first wafer 10A in which the chamfered portion 17A is to be removed. Then, under laser processing conditions similar to those used to form the unevenness 110 described above, the laser beam LB is focused by the focusing unit 43, and the focal point is positioned near the bonding surface 20 between the first wafer 10A and the second wafer 10B as shown in FIG. 6B. The laser beam LB is applied while rotating the first wafer 10A together with the chuck table 41 described above at a predetermined rotation speed (e.g., 60 rpm) in the direction indicated by arrow R1, thereby forming unevenness 120 formed by the ring-shaped modified layer.

In this embodiment, after forming the first unevenness 120 described above, the focal point focused by the focusing unit 43 is moved slightly toward the center of the bonded wafer W, and the laser beam LB is applied under laser processing conditions similar to the above to form a ring-shaped modified layer adjacent to and inward of the ring-shaped modified layer 100 that is initially formed. By performing this procedure multiple times, unevenness 120 formed by multiple ring-shaped modified layers is formed around the entire circumference and near the bonding surface 20 between the first wafer 10A and the second wafer 10B in a region corresponding to the region of the first wafer 10A in which the chamfered portion 17A is to be removed. The ring-shaped unevenness 120 thus formed is formed in a region having a width of 2 to 3 mm from the outer periphery of the bonded wafer W, for example. The ring-shaped unevenness 120 is not limited to being formed in a continuous shape around the entire circumference, but may be formed intermittently at predetermined intervals, for example.

In the forming of unevenness of the above-described embodiment, the laser processing conditions for forming the unevenness 110 and the unevenness 120 are set, for example, to the same laser processing conditions as the wavelength, repetition frequency, and average output set in forming the modified layer described above, but different laser processing conditions are also possible. Additionally, the focal point of the laser beam LB applied in the forming of unevenness described above is preferably set at a position 700 μm±30 μm from the back surface 10Ab of the first wafer 10A forming the bonded wafer W, that is, within a range of 30 μm above and below the position of the bonding surface 20, for example.

The unevenness formed in the forming of unevenness of the present embodiment is formed at the bonding surface 20 between the first wafer 10A and the second wafer 10B corresponding to the region of the first wafer 10A in which the chamfered portion 17A is to be removed. More specifically, the unevenness is formed at any one of the surface 10Aa of the first wafer 10A and the surface 10Ba of the second wafer 10B facing the bonding surface 20 in the region in which the chamfered portion 17A is to be removed, or across the surface 10Aa of the first wafer 10A and the surface 10Ba of the second wafer 10B.

### Forming Release Layer

After forming unevenness as described above, forming of a release layer is performed to form a release layer in a region in which the chamfered portion 17A is to be removed by causing a fluid L that weakens the bonding force between the first wafer 10A and the second wafer 10B to penetrate into the bonding surface 20 between the first wafer 10A and the second wafer 10B. The specific procedure for forming a release layer is described below. The forming of a release layer according to the present disclosure may be performed before or after the forming of a modified layer described above, or at the same time as the forming of a modified layer. In either case, the forming of unevenness described above is performed before the forming of a release layer. The forming of a release layer of the embodiment described below is an example that is performed after the modified layer 100 and the ring-shaped unevenness 120 described above are formed by performing the forming of a modified layer and the forming of unevenness described above.

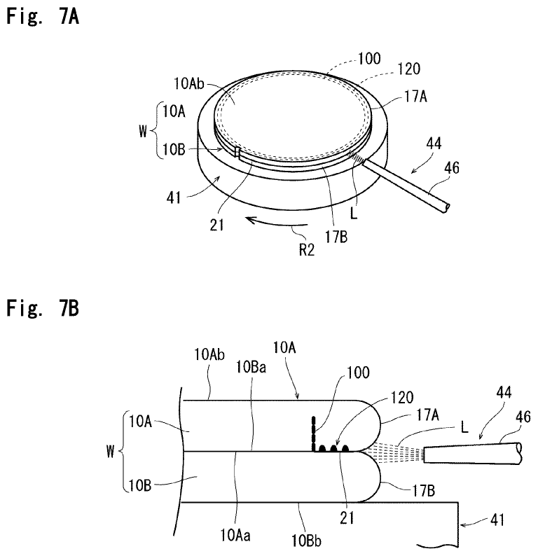

After the modified layer 100 is formed in the forming of a modified layer described above and the unevenness 120 is formed in the forming of unevenness described above, a fluid supply unit 44 is positioned at the side of the bonded wafer W as shown in FIGS. 7A and 7B. The fluid supply unit 44 is disposed in the laser processing apparatus 40 described above, and includes a nozzle 46, which injects a fluid L, such as water (preferably pure water), horizontally to weaken the bonding force between the first wafer 10A and the second wafer 10B. The fluid supply unit 44 includes a moving unit (not shown) for moving the nozzle 46 in the up-down direction and in the horizontal direction toward the center of the chuck table 41. The moving unit is operated to position the tip of the nozzle 46 near the side of the bonding surface 20 of the bonded wafer W, and a fluid supply source (not shown) is operated to supply the fluid L from the tip of the nozzle 46 while rotating the chuck table 41 in the direction indicated by arrow R2. The fluid L may be any fluid that has the effect of weakening the bonding force of the bonding surface 20, and is not limited to the above-mentioned water, but preferably includes at least any one of water vapor, mist, or ammonia.

As described above, in the bonded wafer W of this embodiment, the unevenness 120 is formed at the bonding surface 20 between the first wafer 10A and the second wafer 10B, corresponding to the region of the first wafer 10A in which the chamfered portion 17A is to be removed, and the unevenness 120 facilitates the entry of the fluid L into the bonding surface 20 at the outer periphery of the bonded wafer W. Then, due to the action of the fluid L penetrating into the bonding surface 20 at the outer periphery, the region bonded via siloxane bonding changes to Si—OH—OH—Si bonding. This weakens the bonding force of the bonding surface 20, and as shown in FIG. 7B, a ring-shaped release layer 21 is formed in the region of the first wafer 10A in which the chamfered portion 17A is to be removed.

The unevenness formed in the forming of unevenness according to the present disclosure is preferably formed over the entire circumference of the region in which the chamfered portion 17A is to be removed, as with the unevenness 120 of the embodiment described above. However, as with the unevenness 110 described with reference to FIG. 5A, it may be formed only in a part of the region in which the chamfered portion 17A is to be removed. By causing the fluid L to enter from the region in which the unevenness 110 is formed, the fluid L can penetrate into the entire outer periphery of the bonded wafer W by what is known as capillary action, and a release layer 21 can be formed over the entire region in which the chamfered portion 17A is to be removed.

In the above-described embodiment, the forming of unevenness and the forming of a release layer are performed after performing the forming of a modified layer. However, the forming of unevenness and the forming of a release layer may be performed before the forming of a modified layer described above. It is also possible to perform the forming of a release layer described above at the same time as performing the forming of a modified layer. In this case, the forming of unevenness described above is performed before the forming of a modified layer.

In the above-described embodiment, the forming of a release layer is performed by disposing the fluid supply unit 44, which injects the fluid L, in the laser processing apparatus 40. However, when the forming of a release layer is performed before performing the forming of a modified layer or after performing the forming of a modified layer, the fluid supply unit 44 may be prepared separately from the laser processing apparatus 40, and the fluid L that weakens the bonding force between the first wafer 10A and the second wafer 10B may be caused to penetrate into the bonding surface 20 between the first wafer 10A and the second wafer 10B.

### Removing Chamfered Portion and Grinding

After the release layer 21 is formed by the forming of a release layer described above, removing of the chamfered portion 17A of the first wafer 10A forming the bonded wafer W may be performed. The removing of the chamfered portion may be performed using a unit that applies an external force to the chamfered portion 17A of the first wafer 10A. For example, an external force can be applied by operating an air supply unit (not shown) to inject air from the side of the bonded wafer W toward the release layer 21, thereby removing the chamfered portion 17A with the modified layer 100 as a starting point. Furthermore, the chamfered portion 17A can be removed by inserting a wedge-shaped member (not shown) from the side into the region in which the release layer 21 is formed, and applying an external force thereto. Furthermore, when performing the grinding described below, an external force can be applied to the chamfered portion 17A in the grinding process in which the back surface 10Ab of the first wafer 10A is ground to thin the first wafer 10A. Thus, the grinding can also serve as removing the chamfered portion. The grinding that also serves as removing the chamfered portion is described below.

After the forming of a modified layer, the forming of unevenness, and the forming of a release layer are performed as described above, the bonded wafer W is transported to a grinding apparatus 50 (only a portion of which is shown) shown in FIG. 8 to grind and thin the back surface 10Ab of the first wafer 10A, and also to remove the chamfered portion 17A of the first wafer 10A with the modified layer 100 as a starting point.

The grinding apparatus 50 includes at least a chuck table 51 and a grinding unit 52 shown in FIG. 8. The grinding unit 52 is a unit for grinding the back surface 10Ab of the first wafer 10A of the bonded wafer W held by suction on the chuck table 51, and includes a rotating spindle 52a, which is rotated by a rotation drive mechanism (not shown), a wheel mount 52b, which is attached to the lower end of the rotating spindle 52a, and a grinding wheel 52c attached to the lower surface of the wheel mount 52b. The lower surface of the grinding wheel 52c includes multiple grindstones 52d arranged in a ring shape.

Once the bonded wafer W is transported to the grinding apparatus 50, the bonded wafer W is placed on the chuck table 51 of the grinding apparatus 50 with the first wafer 10A facing upward and the second wafer 10B facing downward, and the suction unit (not shown) is activated to hold the bonded wafer W by suction.

Then, the rotating spindle 52a of the grinding unit 52 is rotated in the direction indicated by arrow R3 in FIG. 8 at 6000 rpm, for example, while the chuck table 51 is rotated in the direction indicated by arrow R4 at 300 rpm, for example. Then, while grinding water is supplied onto the back surface 10Ab of the first wafer 10A by a grinding water supply unit (not shown), a grinding feed unit (not shown) is operated to bring the grindstones 52d into contact with the back surface 10Ab of the first wafer 10A, and the grinding wheel 52c is fed downward to grind as indicated by arrow R5 at a grinding feed rate of 1.0 μm/sec, for example. At this time, the grinding is performed while measuring the thickness of the bonded wafer W with a contact or non-contact measuring gauge (not shown), so that the wafer can be thinned to a desired thickness.

Although not shown in the drawings, the grinding described above can be performed in two steps. For example, the above-mentioned grinding apparatus 50 may include a grinding unit with a predetermined grinding feed rate (e.g., 1.0 μm/sec) that includes a rough grinding wheel having coarse grindstones for rough grinding, and a grinding unit with a predetermined grinding feed rate (e.g., 0.1 μm/sec) that includes a finish grinding wheel having fine grindstones for finish grinding. Rough grinding, in which the back surface 10Ab of the first wafer 10A is roughly ground with the rough grinding wheel and the chamfered portion 17A is removed from the first wafer 10A, and finish grinding, in which the back surface 10Ab is finish-ground with the finish grinding wheel, may be performed successively.

By performing the above-mentioned grinding, as shown in FIG. 8, the first wafer 10A forming the bonded wafer W is thinned, and the grinding process performed by the grinding unit 52 applies an external force to the first wafer 10A to remove the chamfered portion 17A, thereby removing the chamfered portion 17A as broken pieces 17A′ with the modified layer 100 as a starting point as described above. When the radial modified layers 102 described above are formed in the forming of a modified layer, the separation of the chamfered portion 17A into multiple broken pieces 17A′ is facilitated with the radial modified layers 102 as starting points while the chamfered portion 17A is being removed from the first wafer 10A, allowing the chamfered portion 17A to be removed in a desirable manner.

According to the embodiment described above, before removing the chamfered portion 17A, the forming of a release layer and the forming of unevenness, which is performed before the forming of a release layer, are performed. This favorably forms the release layer 21, at which the bonding force is weakened by changing siloxane bonding to Si—OH—OH—Si bonding, in the region of the first wafer 10A in which the chamfered portion 17A is to be removed. As such, the chamfered portion 17A can be easily removed from the first wafer 10A with the modified layer 100 as a starting point, thereby solving a conventional problem in that the chamfered portion 17A is relatively difficult to remove from the first wafer 10A. Furthermore, since a cutting blade is not needed to remove the chamfered portion 17A from the first wafer 10A, there is no risk of damaging the second wafer 10B.

In the above embodiment, an example has been described in which the bonded wafer W is formed by bonding the first wafer 10A and the second wafer 10B via siloxane bonding. However, the bonded wafer W processed according to the present disclosure is not limited to being bonded via siloxane bonding. The bonded wafer W processed by the present disclosure may be a bonded wafer in which the first wafer 10A and the second wafer 10B are bonded via SiCN bonding through nitride bonding, TEOS bonding in which tetraethyl orthosilicate molecules are changed to form a solid having Si—O—Si bonding, or ThOx bonding in which the surface of silicon is heated in an oxidizing atmosphere to form a thermal oxide film for bonding. In either case of bonding, the fluid L supplied in the forming of a release layer described above can weaken the bonding force, allowing the wafer processing method of the above embodiment to easily remove the chamfered portion 17A. Furthermore, the present disclosure can also be applied to a bonded wafer W that is bonded by performing O₂ plasma treatment or N₂ plasma treatment as pretreatment on a bonding surface forming the bonding surface 20 of the bonded wafer W. Furthermore, the fluid L is not limited to water (pure water) as described above, and a mixed fluid in which another fluid is mixed to contain water molecules is also applicable to the present disclosure.

### REFERENCE SIGNS LIST

10A First wafer
10Aa Surface
10Ab Back surface
12A Device
14A Division line
16A Effective region
17A Chamfered portion
17A′ Broken piece
18A Outer peripheral surplus region
10B Second Wafer
10Ba Surface
10Bb Back surface
17B Chamfered portion
20 Bonding surface
21 Release layer
40 Laser processing apparatus
41 Chuck table
42 Laser beam applying unit
43 Focusing unit
44 Fluid supply unit
46 Nozzle
50 Grinding apparatus
51 Chuck table
52 Grinding unit
52a Rotating spindle
52b Wheel mount
52c Grinding wheel
52d Grindstone
100, 102 Modified layer
110, 120 Unevenness
L Fluid (pure water)
W Bonded Wafer

What is claimed is:

1. A wafer processing method for processing a bonded wafer in which a first wafer and a second wafer are bonded, the wafer processing method comprising:
forming a ring-shaped modified layer at an outer periphery of the first wafer by applying a laser beam having a wavelength with transmittability, with a focal point of the laser beam positioned at an inner side adjacent to the chamfered portion; and
before, after, or at a same time as the forming the modified layer, forming a release layer in a region in which the chamfered portion is to be removed by causing a fluid that weakens a bonding force between the first wafer and the second wafer to penetrate into a bonding surface between the first wafer and the second wafer, wherein
the wafer processing method further comprises, before the forming the release layer, forming unevenness for facilitating entry of the fluid by applying a laser beam with a focal point of the laser beam positioned in the region in which the chamfered portion is to be removed.

2. The wafer processing method of claim 1, wherein in the forming the unevenness, the unevenness is formed along an entire circumference or a part of the region in which the chamfered portion is to be removed.

3. The wafer processing method of claim 1, further comprising, after the forming the modified layer and the forming the release layer, removing the chamfered portion from the first wafer.

4. The wafer processing method of claim 1, wherein, after the forming the modified layer and the forming the release layer, grinding of an upper surface of the first wafer is performed to thin the first wafer, and the grinding also serves as removing the chamfered portion.

5. The wafer processing method of claim 1, wherein the first wafer and the second wafer are bonded via Si—O—Si bonding, and
the fluid that weakens the bonding force contains at least one of water, water vapor, mist, or ammonia, and in the forming the release layer, Si—O—Si bonding changes to Si—OH—OH—Si bonding to weaken the bonding force.
